(19) United States
(12) Patent Application Publication
(10) Pub. No.: US 2008/0286897 A1
(43) Pub. Date: Nov. 20, 2008

(54) Method for Manufacturing Image Sensor

(76) Inventor: Chung Kyung JUNG, Anyang-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 12/119,934

(22) Filed: May 13, 2008

(30) Foreign Application Priority Data
May 16, 2007 (KR) 10-2007-0047598

(51) Int. Cl. H01L 31/18

(52) U.S. Cl. 438/70; 257/E31.127

(57) ABSTRACT

Provided is a method for manufacturing an image sensor. In the method, a microlens is formed from an oxide layer. The oxide layer used for the microlenses can be formed using a nitrogen gas as dopant. A plurality of photoresist patterns can be formed on the oxide layer, and the oxide layer can be etched using the photoresist patterns as a mask to form-oxide layer microlenses having a constant curvature. In a further embodiment, a plasma treatment can be applied to the photoresist patterns during forming of the oxide layer microlenses.

### CROSS-REFERENCE TO RELATED APPLICATION

The present application claims the benefit under 35 U.S.C. §119 of Korean Patent Application No. 10-2007-0047598, filed May 16, 2007, which is hereby incorporated by reference in its entirety.

### BACKGROUND

According to a related art, a method of forming microlenses in a manufacturing process of an image sensor includes performing a photolithography process using a special photoresist for microlenses, and reflowing the photoresist.

However, according to the related art, since an amount of the removed photoresist during the reflowing of the photoresist increases, gaps are generated between the microlenses to reduce an amount of incident light, which results in a defective image.

For organic microlenses, particles, which are generated while sawing a wafer during a post process such as packaging and a bump in a semiconductor chip mounting operation, damage the microlenses or adhere to the microlenses to cause a defective image.

Also, in related art microlenses, a difference in focal length to a transverse axis and a diagonal axis may be generated while the microlenses are formed. Consequently, crosstalk to adjacent pixels can be generated.

### BRIEF SUMMARY

Embodiments of the present invention provide a method for manufacturing an image sensor adopting microlenses that use an oxide layer.

According to embodiments, a method for manufacturing an image sensor is provided that can improve the property of oxide layer microlenses in realizing microlenses that use an oxide layer.

A method for manufacturing an image sensor according to an embodiment of the present invention can minimize a gap between microlenses.

In one embodiment, a method for manufacturing an image sensor includes: providing a substrate including a photodiode; forming an oxide layer on the substrate using nitrogen gas as dopant; forming a plurality of photoresist patterns having a predetermined interval on the oxide layer; and etching the oxide layer using the photoresist patterns as a mask to form oxide layer microlenses having a constant curvature.

The details of one or more embodiments are set forth in the accompanying drawings and the description below. Other features will be apparent from the description and drawings, and from the claims.

### BRIEF DESCRIPTION OF THE DRAWINGS

FIGS. 1 to 5 are cross-sectional views for describing a method for manufacturing an image sensor according to an embodiment.

FIG. 6 is a cross-sectional view for describing a method for manufacturing an image sensor according to another embodiment.

### DETAILED DESCRIPTION

Hereinafter, a method for manufacturing an image sensor according to an embodiment will be described with reference to the accompanying drawings.

In the description of embodiments, it will be understood that when a layer (or film) is referred to as being ‘on’ another layer or substrate, it can be directly on another layer or substrate, or intervening layers may also be present. Further, it will be understood that when a layer is referred to as being ‘under’ another layer, it can be directly under another layer, or one or more intervening layers may also be present. In addition, it will also be understood that when a layer is referred to as being ‘between’ two layers, it can be the only layer between the two layers, or one or more intervening layers may also be present.

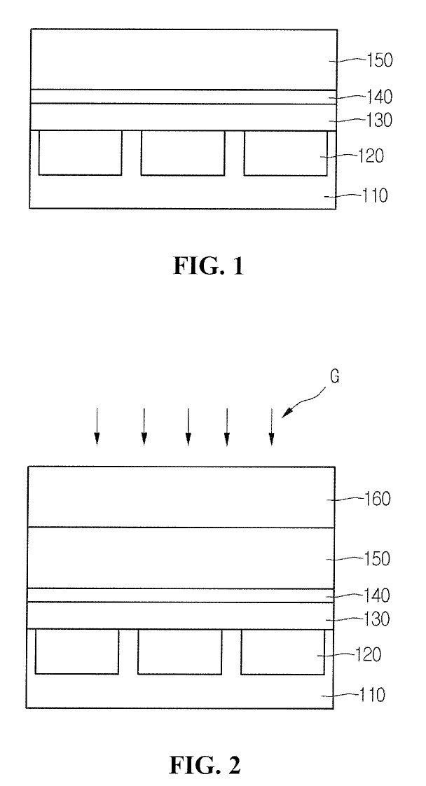

FIGS. 1 to 5 are cross-sectional views illustrating a manufacturing process of an image sensor according to an embodiment.

Referring to FIG. 1, an interlayer dielectric 130 can be formed on a substrate II 0 including photodiodes 120.

The interlayer dielectric 130 can be formed in multi-layers. In one embodiment, a first interlayer dielectric can be formed on the substrate 110. Then, a light blocking layer (not shown) for inhibiting light from being incident to regions other than regions of the photodiodes 120 can be formed, and another interlayer dielectric can be formed on the light blocking layer and first interlayer dielectric.

In a further embodiment, a passivation layer (not shown) for protecting devices from moisture and scratches can be formed on the interlayer dielectric 130.

A dyeable resist can be coated on the interlayer dielectric 130. Exposure and developing processes can be performed with respect to the dyeable resist to form a color filter layer 140. The color filter layer 140 can include red (R), green (G), and blue (B) color filters (not shown) filtering light by a wavelength band.

A planarization layer 150 for securing a planarization degree can be formed on the color filter layer 140 to control a focal length and form a lens layer.

Next, referring to FIG. 2, an oxide layer 160 for a microlens can be formed on the planarization layer 150 using nitrogen gas as dopant.

The oxide layer 160 can be formed by depositing an oxide film at temperature below about 200° C. The oxide layer 160 can be formed using SiO₂, but embodiments are not limited thereto. In certain embodiments, the oxide layer 160 can be formed using chemical vapor deposition (CVD), physical vapor deposition (PVD), or plasma enhanced CVD (PECVD).

Because the oxide layer 160 is deposited at a temperature below 200° C., a dense layer can be difficult to obtain. In this circumstance, voids and pits may form in the oxide layer 160, having a serious influence on layer quality.

According to an embodiment, to solve this limitation, formation of the voids and pits generated on the surface of the oxide layer 160 can be controlled using nitrogen gas (G) as dopant in the embodiment.

However, when the amount of N₂ in the oxide layer increases, the layer's refractive index may be reduced. Therefore, according to an embodiment, the atomic % of the nitrogen is controlled to 3% or less, such that the void and pit formation can be controlled and the excellent characteristics of oxide layer microlenses can be maintained.

In an operation of forming the oxide layer 160 according to an embodiment, the oxide layer 160 is formed using a nitrogen gas (G) as a dopant together with a material for forming the oxide layer 160, so that formation of void and pit generated on the surface of the oxide layer 160 can be controlled.

The operation of forming the oxide layer 160 according to an embodiment can include forming the oxide layer 160 using a material for forming an oxide layer 160, and performing a nitrogen gas treatment on the oxide layer 160 using nitrogen gas (G) as dopant.

In another embodiment, the operation of forming the oxide layer 160 can include forming the oxide layer using a first nitrogen gas (G) dopant together with a material for forming the oxide layer 160 when depositing the material for forming the oxide layer 160, and then performing a nitrogen gas treatment on the oxide layer 160 using a second nitrogen gas (not shown) as a dopant to more effectively remove formation of void and pit generated on the surface of the oxide layer 160.

According to embodiments of the present invention, the oxide layer 160 can be formed using nitrogen gas (G) as dopant provided at up to 30 sccm.

The effects of using nitrogen gas according to certain embodiments of the subject method is described using the following experiments. In a first experiment, while the oxide layer 160 was being formed, the flux of nitrogen gas (G) aws added at 0 sccm. That is, no nitrogen gas was added in the first experiment. In a second experiment, while the oxide layer 160 was formed, the flux of nitrogen gas (G) was added at 20 sccm. In a third experiment, while the oxide layer 160 was formed, the flux of nitrogen gas (G) was added at 30 sccm.

Scanning electron microscope (SEM) images were obtained for each experiment and examined. For the first experiment, voids and pits were generated. For the second experiment, voids and pits were not generated. Also, for the third experiment, it was observed that the refractive index tended to increase and transmittance tended to reduce.

Through the above process, a process condition for optimizing a process of a new oxide layer microlens has been developed.

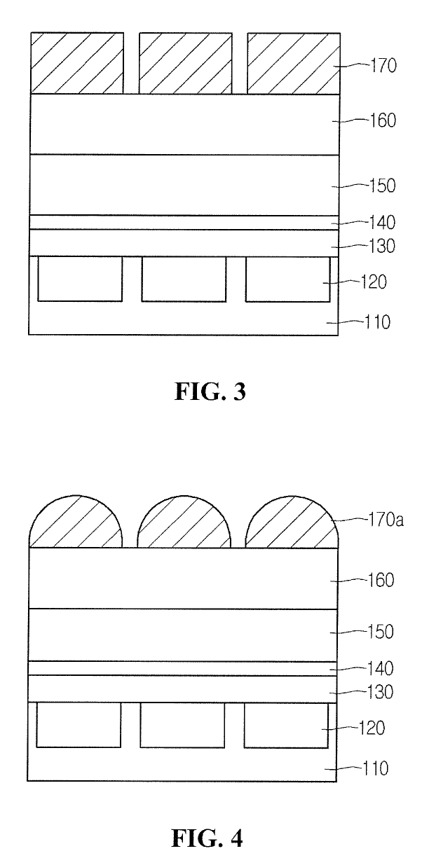

Referring to FIG. 3, a plurality of photoresist patterns 170 can be formed on the oxide layer 160. The photoresist patterns 170 can be formed having a predetermined interval.

In one embodiment, the photoresist patterns 170 can be formed by coating a photoresist layer (not shown) on the oxide layer 160, and then selectively patterning the photoresist layer through an exposure and developing process using a mask for microlenses (not shown).

In an embodiment, the photoresist patterns 170 can be formed thicker than the oxide layer 160 because the etch stop characteristic of the photoresist patterns 170 is lower than that of the oxide layer 160.

According to an embodiment, the oxide layer 160 can be etched using the photoresist patterns 170 as an etch mask. In another embodiment, the photoresist patterns 170 can be reflowed to form microlens patterns 170a, and then the oxide layer 160 can be etched using the microlens patterns 170a as an etch mask.

For example, referring to FIG. 4, the microlens patterns 170a can be formed by placing a semiconductor substrate 110 including the photoresist patterns 170 on a hot plate (not shown), and performing a heat treatment at about 150° C. or more to reflow the photoresist patterns 170 into hemisphere-shaped microlens patterns 170a.

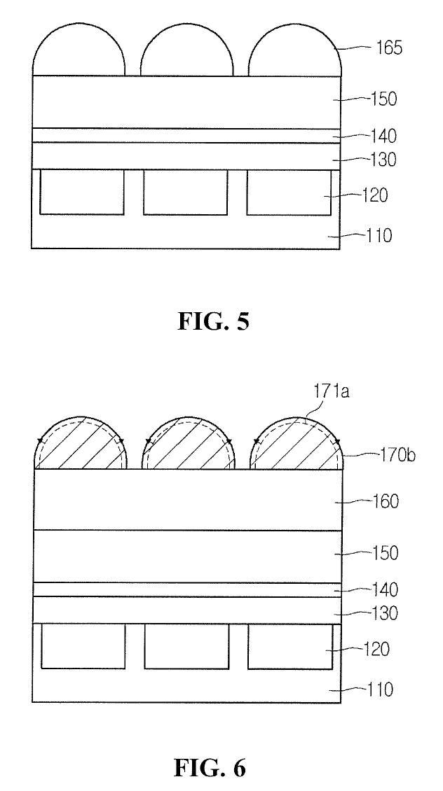

Referring to FIG. 5, the oxide layer 160 can be etched using the microlens patterns 170a as a mask to form oxide layer microlenses 165 having a constant curvature.

According to embodiments of the present invention, voids and oxide pits can be inhibited from being generated in an oxide layer for microlenses. Further embodiments are capable of inhibiting void and pit generation without adversely changing the refractive index and transmittance of an oxide layer for microlenses. Accordingly, embodiments include using a nitrogen gas treatment during forming the microlens oxide layer so that device characteristics can be improved.

FIG. 6 is a view illustrating a microlens forming process of a method for manufacturing an image sensor according to another embodiment.

Here, the oxide layer 160 can be etched using the photoresist patterns 170 as an etch mask. Alternatively, the photoresist patterns 170 can be reflowed to form microlens patterns 171a (170a of FIG. 4), and then the oxide layer 160 can be etched using the microlens patterns 170a as an etch mask.

According to the embodiment illustrated in FIG. 6, a plasma treatment is additionally performed on the photoresist patterns 170 or the microlens patterns 170a when the oxide layer 160 is etched using the photoresist patterns 170 or the microlens patterns 170a as a mask.

For example, the oxide layer 160 can be initially etched using the microlens patterns 171a as a mask.

During the etching process, a plasma treatment can be performed on the microlens patterns 171a to form patterns 170b, such that the oxide layer 160 is secondarily etched using plasma-treated microlens patterns 170b as a mask.

At this point, in an operation of performing plasma treatment on the microlens patterns 171a, source power can be increased by 1.5 times compared to a ratio of source power to bias power during the initial etching in order to raise plasma temperature. This procedure extends, or enlarges, the microlens patterns 170a to form the plasma-treated microlens patterns 170b.

For example, in the case where the ratio of source power to bias power is about 5:1 in the primary etching, the source power is increased by 1.5 times in the primary etching to raise plasma temperature, so that the microlens patterns 170a are extended and thus the plasma-treated microlens patterns 170b can be formed.

Also, for example, in the operation of performing plasma treatment on the microlens patterns 170a, the bias power can be in the range of 200-400 W, and the source power can be in the range of 1200-1400 W. [00481 According to certain embodiments, in the operation of forming the oxide layer microlenses (165 of FIG. 5), the plasma treatment can be preformed on the photoresist patterns 170 or the microlens patterns 171a three or more times.

For example, the oxide layer 160 can be initially etched using the microlens patterns 171a. Then, a first plasma process can be performed to extend the microlens patterns 171a, which have been partially etched during the initial etching process, into the plasma-treated microlens patterns 170b. The oxide layer 160 can continue to be etched, but now is etched with the plasma-treated microlens patterns 170b as an etch mask. After a period of time, a second plasma process can be performed to extend the now partially etched plasma-treated microlens patterns 170b. This etching and plasma treatment steps can be continued until the oxide layer 160 has been etched into the microlenses 165.

By performing the plasma treatment, a gap between the photoresist patterns 170 or the microlens patterns 170a can be reduced. Consequently, a gap between the oxide layer microlenses 165 can be effectively reduced.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method for manufacturing an image sensor, comprising:
providing a substrate including a photodiode;
forming an oxide layer on the substrate using nitrogen gas as a dopant;
forming a plurality of photoresist patterns on the oxide layer; and
forming oxide layer microlenses from the oxide layer using the photoresist patterns as a mask.

2. The method according to claim 1, wherein the forming of the oxide layer comprises:
using the nitrogen gas while depositing a material for forming the oxide layer.

3. The method according to claim 1, wherein the forming of the oxide layer comprises:
depositing a material for forming the oxide layer; and
performing a nitrogen gas treatment using the nitrogen gas on the deposited material for forming the oxide layer.

4. The method according to claim 1, wherein the forming of the oxide layer comprises:
using the nitrogen gas while depositing a material for forming the oxide layer; and
performing a nitrogen gas treatment using additional nitrogen gas.

5. The method according to claim 1, wherein the forming of the oxide layer comprises using gas having the nitrogen in a range of about 3 atomic % or less.

6. The method according to claim 1, wherein the forming of the oxide layer comprises using the nitrogen gas in a range of at most about 30 sccm.

7. The method according to claim 1, wherein the photoresist patterns are formed having a thickness thicker than the oxide layer.

8. The method according to claim 1, wherein forming the photoresist patterns comprises:
coating the substrate with a photoresist; and
performing exposure and developing processes, providing a patterned photoresist.

9. The method according to claim 8, wherein forming the photoresist patterns further comprises performing a reflow process on the patterned photoresist.

10. The method according to claim 1, wherein the forming of the oxide layer microlenses comprises:
initially etching the oxide layer using the photoresist patterns as a mask;
performing a plasma treatment on the photoresist patterns; and
etching the initially etched oxide layer using the plasma-treated photoresist patterns as the mask.

11. The method according to claim 10, wherein the performing of the plasma treatment on the photoresist patterns comprises raising plasma temperature by increasing source power by at least 1.5 times compared to a ratio of source power to bias power in the initial etching

12. The method according to claim 10, wherein the plasma treatment extends the photoresist patterns.

13. The method according to claim 10, wherein the performing of the plasma treatment on the photoresist patterns comprises using bias power in a range of 200-400 W, and source power in a range of 1200-1400 W.

14. The method according to claim 10, wherein the forming of the oxide layer microlenses further comprises repeatedly performing the plasma treatment on the photoresist patterns and etching the oxide layer using each subsequent plasma-treated photoresist patterns as the mask.

15. The method according to claim 14, wherein the plasma treatment and etching using each subsequent plasma-treated photoresist patterns is performed at least three times.

16. The method according to claim 1, wherein the plurality of photoresist patterns are formed having a predetermined interval on the oxide layer.

17. The method according to claim 1, wherein the oxide layer microlenses are formed having a constant curvature.

18. The method according to claim 1, further comprising:
forming an interlayer dielectric on the substrate; and
forming a color filter layer on the interlayer dielectric before forming the oxide layer on the substrate.

19. The method according to claim 18, further comprising, after the forming of the color filter layer, forming a planarization layer on the color filter layer.
